(19) United States
(12) Patent Application Publication
(10) Pub. No.: US 2019/0219777 A1
(43) Pub. Date: Jul. 18, 2019

(54) OPTICAL CONNECTION STRUCTURE

(71) Applicant: SUMITOMO ELECTRIC INDUSTRIES, LTD., Osaka-shi, Osaka (JP)

(72) Inventors: Sho YAKABE, Yokohama-shi, Kanagawa (JP); Takuro WATANABE, Yokohama-shi, Kanagawa (JP); Tomomi SANO, Yokohama-shi, Kanagawa (JP)

(73) Assignee: SUMITOMO ELECTRIC INDUSTRIES, LTD., Osaka-shi, Osaka (JP)

(21) Appl. No.: 16/318,800

(22) PCT Filed: Jul. 28, 2017
(86) PCT No.: PCT/JP2017/027506

§ 371 Date: Jan. 18, 2019

(30) Foreign Application Priority Data
Aug. 31, 2016 (JP) 2016-169185

(51) Int. Cl. G02B 6/42; G02B 6/122; H01S 5/022; H01L 31/0232

(52) U.S. Cl. CPC G02B 6/4204; G02B 6/122; H01S 5/183; H01L 31/0232; H01S 5/022

(57) ABSTRACT

A lens component has a lens surface having a lens, a bottom surface facing an optical waveguide film, a first area located between the lens surface and the bottom surface, and transmitting light, and second areas provided on at least both sides of the first area. The optical waveguide film has mounting surfaces. The second areas have guide holes opened in the first end faces. The optical waveguide film has projecting parts fitted in the guide holes composed of a core layer, in the respective mounting surfaces. A height of the bottom surface to each first end face is larger than a height from each mounting surface to a surface of the optical waveguide film.

### TECHNICAL FIELD

An aspect of the present invention relates to an optical connection structure.

This application claims priority based on Japanese Patent Application No. 2016-169185 filed on Aug. 31, 2016, the entire contents of which are incorporated herein by reference.

### BACKGROUND ART

In Patent Literature 1, an optical device comprising a structure for connecting an optical waveguide formed on a substrate, and an optical fiber is disclosed. This optical device includes a substrate, a lens array part, and a connector part. On the substrate, a plurality of waveguides having respective light reflection surfaces are formed. The lens array part comprises a waveguide side lens array facing the plurality of waveguides, and are provided in such a way that a plurality of lenses are positioned relative to the corresponding respective light reflection surfaces. The connector part includes an optical transmission path side lens array having a plurality of lenses, and the plurality of lenses are provided in such a way as to be positioned relative to the corresponding respective lenses of the waveguide side lens array. In the connector part, a plurality of optical transmission paths are inserted. The plurality of optical transmission paths are positioned and fixed to the corresponding respective lenses of the optical transmission path side lens array.

### CITATION LIST

### Patent Literature

Patent Literature 1: Japanese Unexamined Patent Publication No. 2015-184667

### SUMMARY OF INVENTION

A first optical connection structure according to an embodiment comprises: an optical waveguide film including a planar optical waveguide formed on a substrate surface, and a light reflection surface inclined to both a normal line of the substrate surface and an optical axis of the planar optical waveguide; and a lens component provided on the optical waveguide film, and having a lens optically coupled to the light reflection surface. The optical waveguide film has an under-cladding layer, an over-cladding layer provided over the under-cladding layer, and a core layer provided between the under-cladding layer and the over layer. The lens component has a first surface having the lens, a second surface located on a back side of the first surface, and facing the optical waveguide film, a first area located between the first surface and the second surface, and transmitting light, and second areas provided on at least both sides of the first area in a direction along the substrate surface. The optical waveguide film has mounting surfaces to which the under-cladding layer is exposed, the mounting surfaces facing the second areas. The respective second areas have a first guide hole formed on one side of the first area, and a second guide hole formed on another side of the first area, the first guide hole and the second guide hole being opened in respective first end faces facing the mounting surfaces. The optical waveguide film has a first projecting part composed of at least the core layer, and fitted in the first guide hole, and a second projecting part composed of at least the core layer, and fitted in the second guide hole, in the respective mounting surfaces. A height from the second surface to each of the first end faces is larger than a height from each of the mounting surfaces to a surface of the optical waveguide film.

A second optical connection structure according to an embodiment comprises: an optical waveguide film including a planar optical waveguide formed on a substrate surface, and a light reflection surface inclined to both a normal line of the substrate surface and an optical axis of the planar optical waveguide; and a lens component provided on the optical waveguide film, and having a lens optically coupled to the light reflection surface. The optical waveguide film has an under-cladding layer, an over-cladding layer provided over the under-cladding layer, and a core layer provided between the under-cladding layer and the over-cladding layer. The lens component has a first surface having the lens, a second surface located on a back side of the first surface, and facing the optical waveguide film, a first area located between the first surface and the second surface, and transmitting light, and second areas provided on at least both sides of the first area in a direction along the substrate surface. The optical waveguide film has mounting surfaces to which the under-cladding layer is exposed, the mounting surfaces facing the second areas. An outer surface at a portion located on a side of the substrate surface with respect to a plane including the first surface in each of the second areas is in contact with a laminated end face of the core layer and the over-cladding layer constituting a contour of the mounting surface. A height from the second surface to a first end face of each of the second areas facing the mounting surface is larger than a height from each of the mounting surfaces to a surface of the optical waveguide film.

### BRIEF DESCRIPTION OF DRAWINGS

FIG. 1 is a side view illustrating a configuration of a substrate apparatus comprising an optical connection structure according to a first embodiment.

FIG. 2 is a sectional view schematically illustrating a structure for transmitting and receiving an optical signal between two CPU substrates, that is, an optical connection structure of this embodiment.

FIG. 3A is a top view of a lens component.

FIG. 3B is a side sectional view of the lens component.

FIG. 3C is a bottom view of the lens component.

FIG. 4 is a sectional view illustrating a state in which the lens component is mounted on an optical waveguide film on a CPU substrate.

FIG. 5 is a sectional view partially enlarging and illustrating an optical coupling structure according to a second embodiment.

### DESCRIPTION OF EMBODIMENTS

### Technical Problem

In the structure described in Patent Literature 1, a projecting and flat rectangular positioning structure is provided on a back surface of the lens array. However, in such a positioning structure, the flat shape is small, and therefore pressure when resin is filled needs to be increased in order to precisely mold a corner. When the filling pressure is increased, molding accuracy of a lens surface is lowered. Therefore, there is a problem that the corner is difficult to be precisely molded, and positioning accuracy is suppressed.

An object of this disclosure is to provide an optical connection structure capable of accurately positioning a lens component such as a lens array.

### Advantageous Effect of Disclosure

According to an optical connection structure of this disclosure, it is possible to accurately position a lens component.

### Description of Embodiments

First, contents of embodiments of this disclosure will be listed and described. A first optical connection structure according to an embodiment comprises: an optical waveguide film including a planar optical waveguide formed on a substrate surface, and a light reflection surface inclined to both a normal line of the substrate surface and an optical axis of the planar optical waveguide; and a lens component provided on the optical waveguide film, and having a lens optically coupled to the light reflection surface. The optical waveguide film has an under-cladding layer, an over-cladding layer provided over the under-cladding layer, and a core layer provided between the under-cladding layer and the over-cladding layer. The lens component has a first surface having the lens, a second surface located on a back side of the first surface, and facing the optical waveguide film, a first area located between the first surface and the second surface, and transmitting light, and second areas provided on at least both sides of the first area in a direction along the substrate surface. The optical waveguide film has mounting surfaces to which the under-cladding layer is exposed, the mounting surfaces facing the second areas. The respective second areas have a first guide hole formed on one side of the first area, and a second guide hole formed on another side of the first area, the first guide hole and the second guide hole being opened in respective first end faces facing the mounting surfaces. The optical waveguide film has a first projecting part composed of at least the core layer, and fitted in the first guide hole, and a second projecting part composed of at least the core layer, and fitted in the second guide hole, in the respective mounting surfaces. A height from the second surface to each of the first end faces is larger than a height from each of the mounting surfaces to a surface of the optical waveguide film.

In this optical connection structure, the respective second areas have the first guide hole and the second guide hole, the optical waveguide film has the first projecting part fitted in the first guide hole, and the second projecting part fitted in the second guide hole. Therefore, the lens component can be accurately positioned relative to the optical waveguide film by this fitting. In addition, the height from the second surface to each first end face is larger than the height from each mounting surface to the surface of the optical waveguide film. Therefore, the first end faces of the second areas can reliably come into contact with the mounting surfaces, and the first guide hole and the second guide hole can be reliably fitted to the first projecting part and the second projecting part, respectively.

In the above first optical connection structure, the first guide hole and the second guide hole may penetrate as far as second end faces located on the back side of the first end face, and each may have a first hole part extending from the first end face, a second hole part extending from the second end face, and a third hole part connecting the first hole part and the second hole part, an inner diameter of each of the first hole parts may be smaller than an inner diameter of each of the second hole parts, and an inner diameter of each of the third hole parts may gradually expand from one end on a side of the first hole part to another end on a side of the second hole part. Thus, the first guide hole and the second guide hole have openings in the second end faces, so that the relative position between the optical connector and the lens component can be accurately positioned through the guide pins. The inner diameter of each first hole part is smaller than the inner diameter of each second hole part, the inner diameter of each third hole part gradually expands from the side of the first hole part to the side of the second hole part. Accordingly, when the first guide hole and the second guide hole are formed by rod-like dies, the rod-like dies are easily pull out from the sides of the second hole parts.

A second optical connection structure according to an embodiment comprises: an optical waveguide film including a planar optical waveguide formed on a substrate surface, and a light reflection surface inclined to both a normal line of the substrate surface and an optical axis of the planar optical waveguide; and a lens component provided on the optical waveguide film, and having a lens optically coupled to the light reflection surface. The optical waveguide film has an under-cladding layer, an over-cladding layer provided over the under-cladding layer, and a core layer provided between the under-cladding layer and the over-cladding layer. The lens component has a first surface having the lens, a second surface located on a back side of the first surface, and facing the optical waveguide film, a first area located between the first surface and the second surface, and transmitting light, and second areas provided on at least both sides of the first area in a direction along the substrate surface. The optical waveguide film has mounting surfaces to which the under-cladding layer is exposed, the mounting surfaces facing the second areas. An outer surface at a portion located on a side of the substrate surface among two portions sectioned by a plane obtained by extending the second surface in each of the second areas is in contact with a laminated end face of the core layer and the over-cladding layer constituting a contour of the mounting surfaces. A height from the second surface to a first end face of each of the second areas facing the mounting surface is larger than a height from each of the mounting surfaces to a surface of the optical waveguide film.

In this optical connection structure, the outer surface at the portion located on the side of the substrate surface among the two portions sectioned by the plane obtained by extending the second surface in each of the second areas is in contact with the laminated end face of the core layer and the over-cladding layer constituting the contour of the mounting surface. Consequently, the lens component can be accurately positioned relative to the optical waveguide film. In addition, the height from the second surface to each first end face is larger than the height from each mounting surface to the surface of the optical waveguide film. Accordingly, the first end faces of the second areas can be reliably brought into contact with the mounting surfaces, and the outer surfaces at the above portions of the second areas can be reliably brought into contact with the laminated end faces.

In the above second optical connection structure, the respective second areas may have a third guide hole formed on one side of the first area, and a fourth guide hole formed on another side of the first area, the third guide hole and the fourth guide hole being opened in respective second end faces located on back sides of the first end faces. The lens component has such a third guide hole and a fourth guide hole, so that a relative position between the optical connector and the lens component can be accurately positioned through guide pins.

The first and second optical connection structures each may further comprise a refractive index matching agent filling a gap between the second surface and the optical waveguide film. Consequently, it is possible to suppress Fresnel reflection at the second surface and the surface of the optical waveguide film, and to reduce an optical loss.

### Details of Embodiment

Specific examples of optical connection structures according to embodiments of this disclosure will be hereinafter described with reference to the drawings. The present invention is defined by the terms of the claims, rather than the embodiments and examples of embodiment described above, it is intended to include any modifications within the meaning and range of equivalency of the claims. In the following description, the same components in the description of the drawing are denoted by the same reference numerals, and overlapped description will be omitted.

### First Embodiment

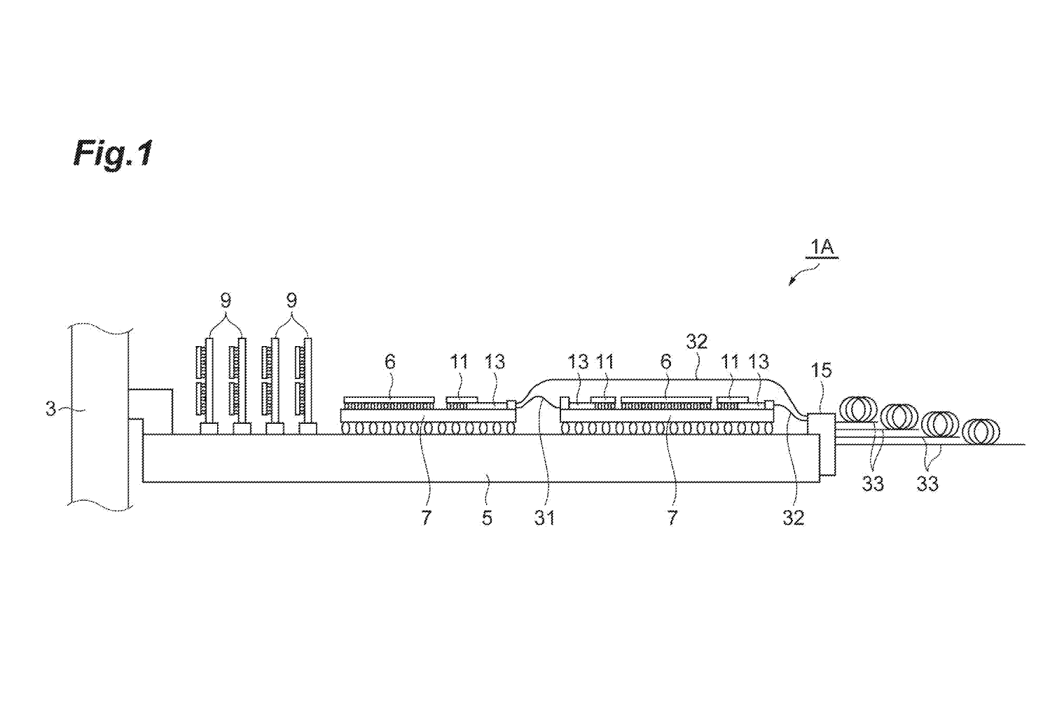

FIG. 1 is a side view illustrating a configuration of a substrate apparatus 1A comprising an optical connection structure according to a first embodiment. This substrate apparatus 1A is connected to a backplane 3 in a server system, for example. As illustrated in FIG. 1, this substrate apparatus 1A comprises a plate-like base 5, a plurality of CPU substrates 7 provided on one surface of the base 5, and a plurality of memory substrates 9. Each CPU substrate 7 is a PCB substrate, and a back surface of each CPU substrate 7 is mounted on the base 5 by flip chip bonding. A CPU 6, and a light receiving element or a light emitting element (herein referred to as a light receiving/emitting element 11) electrically connected to the CPU 6 are mounted on a principal surface on a side opposite to the back surface of each CPU substrate 7. The light receiving/emitting element 11 converts an electric signal output from the CPU 6 into an optical signal, and outputs the optical signal to a planar optical waveguide 13 provided on the CPU substrate 7. The light receiving/emitting element 11 converts the optical signal received from the planar optical waveguide 13 into an electric signal, and outputs the electric signal to the CPU 6. The planar optical waveguide 13 is optically coupled to the planar optical waveguide 13 of another CPU substrate 7 through an inter-substrate optical waveguide 31. The inter-substrate optical waveguide 31 is, for example, a flexible optical waveguide or an optical fiber. The planar optical waveguide 13 is optically coupled to an input/output port 15 of the substrate apparatus 1A through another optical waveguide 32 in the substrate apparatus 1A. Another optical waveguide 32 is, for example, a flexible optical waveguide or an optical fiber. To the input/output port 15, a plurality of optical fibers 33 for performing optical communication with another apparatus is coupled.

The communication between the CPU substrates 7, and the transmission and reception between the input/output port 15 and the CPU substrates 7 are thus performed by using an optical signal, so that the following advantages are obtained. In a conventional system in which communication is performed by using only an electric signal, the higher the frequency is, the larger a loss is, and therefore problems such as limitation of a transmission distance, and increase in power consumption arise. By using an optical signal as described above, it is possible to shorten an electric wire for high frequency transmission and reception between the CPU substrates 7, or the CPU substrate 7 and the input/output port 15.

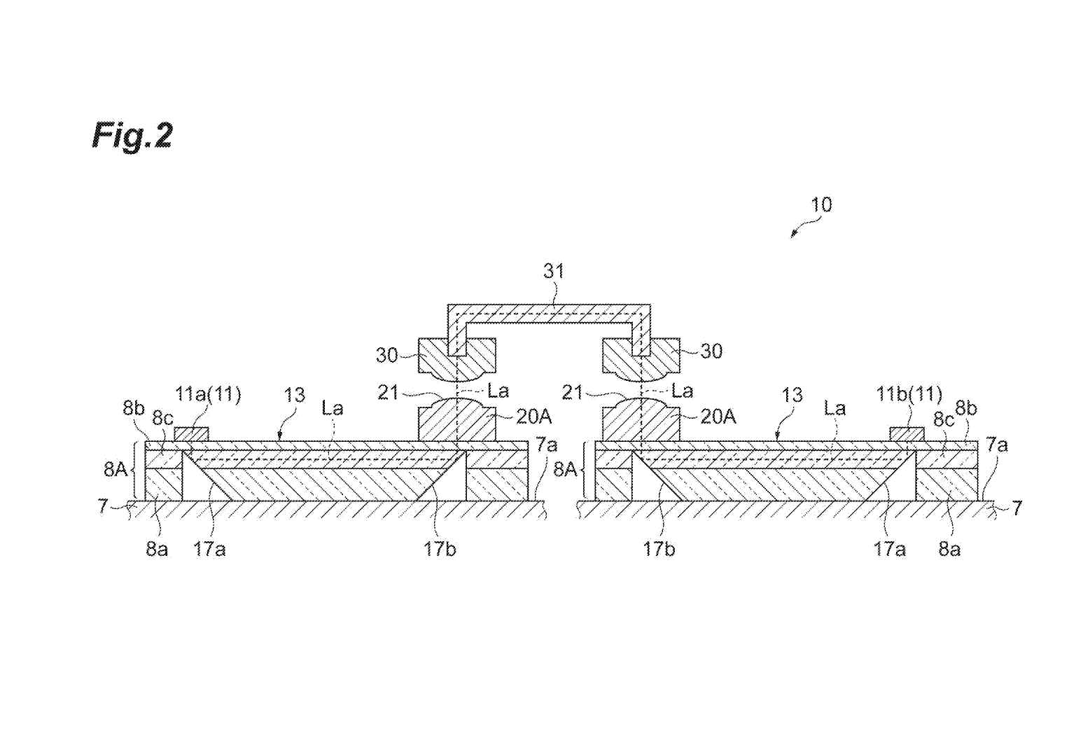

FIG. 2 is a sectional view schematically illustrating a structure for transmitting and receiving an optical signal La between the two CPU substrates 7, that is, an optical connection structure 10 of this embodiment. As illustrated in FIG. 2, on substrate surfaces 7a of the CPU substrate 7, optical waveguide films 8A are formed. The optical waveguide film 8A on each CPU substrate 7 includes at least the one planar optical waveguide 13. Each planar optical waveguide 13 has light reflection surfaces 17a, 17b on both ends thereof. The light reflection surfaces 17a, 17b are inclined to both a normal line of the substrate surface 7a and an optical axis of the planar optical waveguide 13. The light reflection surfaces 17a, 17b each reflect the optical signal La propagated through the planar optical waveguide 13 in the direction intersecting with the substrate surface 7a of the CPU substrate 7, or each guide the optical signal La incident from the direction intersecting with the substrate surface 7a of the CPU substrate 7 into the planar optical waveguide 13. The light reflection surfaces 17a, 17b each form an angle of 45 degrees to the optical axis of the planar optical waveguide 13, for example. In FIG. 2, the one planar optical waveguide 13 is illustrated on each CPU substrate 7. However, a plurality of the planar optical waveguides 13 may be provided on each CPU substrate 7.

Each optical waveguide film 8A has an under-cladding layer 8a, an over-cladding layer 8b, and a core layer 8c. These layers are composed of a material such as epoxy resin, for example. A refractive index of the core layer 8c is higher than the refractive index of the under-cladding layer 8a, and the refractive index of the over-cladding layer 8b. The over-cladding layer 8b is provided over the under-cladding layer 8a. The core layer 8c is provided between the under-cladding layer 8a and the over-cladding layer 8b, and is covered by these cladding layers 8a, 8b. The core layer 8c is worked in a linear shape, so that the planar optical waveguide 13 is constituted. In an example, the thickness of the core layer 8c is 25 μm, and the thickness of the over-cladding layer 8b is 10 μm to 15 μm.

In the planar optical waveguide 13, on the first light reflection surface 17a of the first CPU substrate 7, a vertical cavity surface emitting laser (VCSEL) 11a being one of the light receiving/emitting elements 11 is provided. The VCSEL 11a is a light emitting element that converts an electric signal output from the CPU 6 of the CPU substrate 7 into an optical signal La. In the VCSEL 11a, a light-emitting surface is disposed in such a way as to face the substrate surface 7a of the CPU substrate 7, and is optically coupled to the light reflection surface 17a. The optical signal La output from the VCSEL 11a is reflected by the light reflection surface 17a to be guided to the planar optical waveguide 13. A photodiode 11b is provided on the first light reflection surface 17a of the second CPU substrate 7. The photodiode 11b is a light receiving element that converts an optical signal La output from the first CPU substrate 7 into an electric signal, and provides the CPU 6 of this CPU substrate 7 with the electric signal. In the photodiode 11b, a light-receiving surface is disposed in such a way as to face the substrate surface 7a of the CPU substrate 7, and is optically coupled to the light reflection surface 17a. The optical signal La propagated through the planar optical waveguide 13 is reflected by the light reflection surface 17a to be guided to the light-receiving surface of the photodiode 11b.

On the second light reflection surface 17b of each CPU substrate 7, a lens component 20A (lens array) is provided. The lens component 20A has at least one lens 21 optically coupled to each light reflection surface 17b. Optical connectors 30 with lenses are connected to these lens components 20A, and these optical connectors 30 are optically coupled to each other through the inter-substrate optical waveguide 31. The optical connectors 30 are detachably provided in the lens components 20A.

In the first CPU substrate 7, the optical signal La output from the VCSEL 11a is reflected by the light reflection surface 17a to be guided to the planar optical waveguide 13. The optical signal La is propagated through the planar optical waveguide 13, and is reflected by the light reflection surface 17b to be incident on the lens component 20A. The optical signal La is collimated by each lens 21, and thereafter incident on the optical connector 30. Then, the optical signal is propagated through the inter-substrate optical waveguide 31, and thereafter is incident on the lens component 20A on the second CPU substrate 7 through the second optical connector 30. The optical signal La is reflected by the light reflection surface 17b while being condensed by each lens 21, and is guided to the planar optical waveguide 13 on the second CPU substrate 7. The optical signal La is propagated through the planar optical waveguide 13, and is reflected by the light reflection surface 17a to reach the photodiode 11b.

In a case where the optical signal La is incident from the propagation direction of the planar optical waveguide 13, that is in the direction along the substrate surface 7a, or the optical signal La is emitted to the above direction, the thickness of the planar optical waveguide 13 is thin, and therefore it is difficult to connect the lens array and the optical connector, and enlargement of the whole apparatus is needed. Like this embodiment, incidence and emission of the optical signal La is performed along the direction intersecting with the substrate surface 7a (suitably, vertical direction), so that connection of the lens component 20A and the optical connector 30 become easy, and can contribute to downsizing of the whole apparatus.

In this embodiment, each CPU substrate 7 is optically coupled through the detachable optical connector 30 and the inter-substrate optical waveguide 31. Consequently, when a problem such as disconnection of the inter-substrate optical waveguides 31 arises, the optical connector 30 and the inter-substrate optical waveguides 31 only need to be replaced, and replacement of the CPU substrate 7 is unnecessary. Additionally, at the time of system change, change of an optical wire between the CPU substrates 7 is also easy.

Furthermore, the planar optical waveguides 13 on the CPU substrates 7 and the inter-substrate optical waveguide 31 are coupled through the lens components 20A and the optical connectors 30. Accordingly, both can be coupled by enlarged collimated light, and it is possible to suppress a coupling loss by a tolerance between the components, and to suppress influence on optical coupling efficiency by dirt or dust.

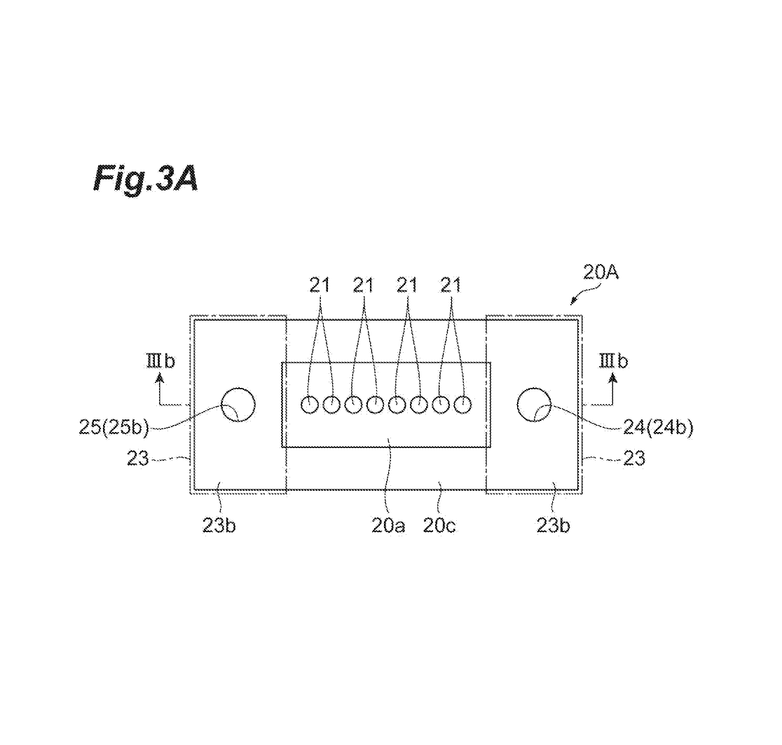

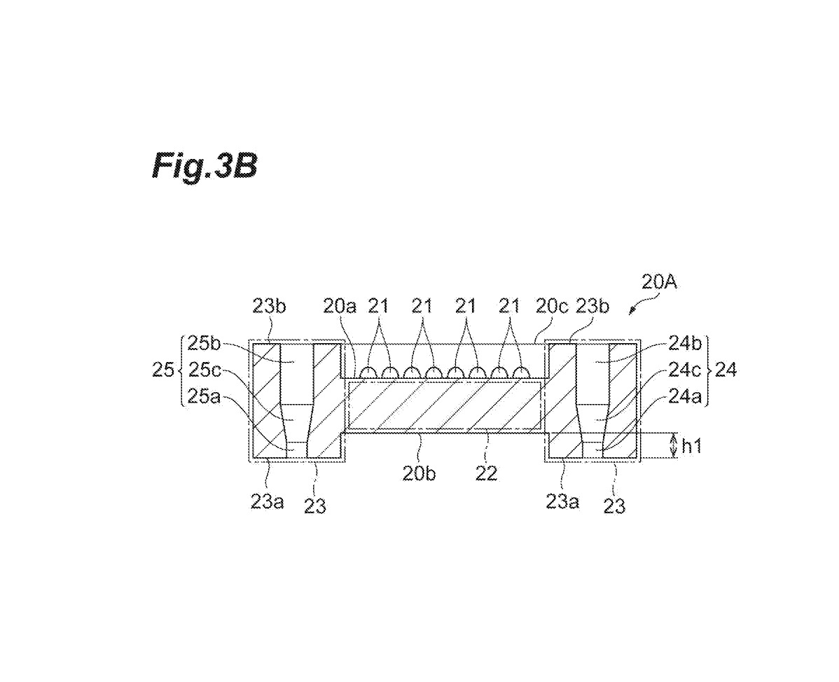

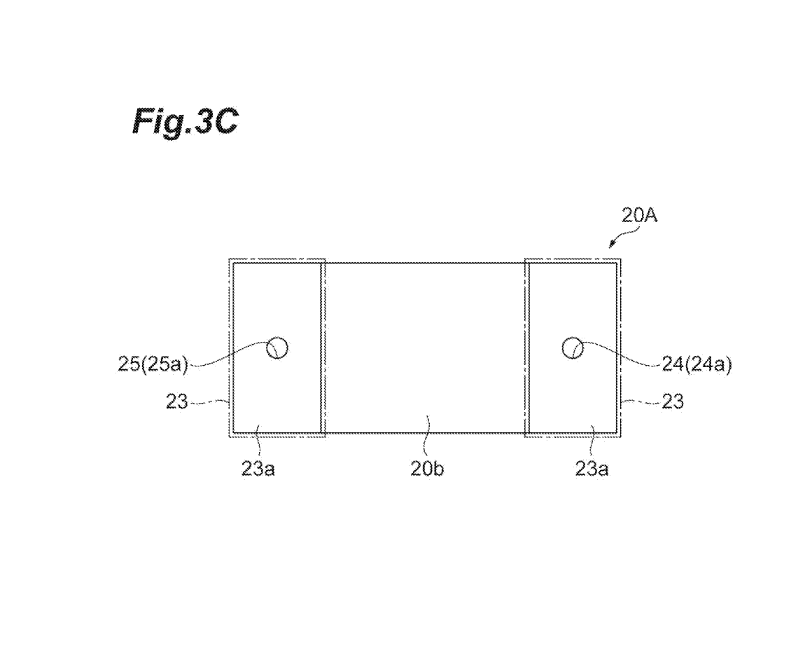

FIG. 3A is a top view of the lens component 20A. FIG. 3B is a side sectional view of the lens component 20A. FIG. 3C is a bottom view of the lens component 20A. As illustrated in these figures, each lens component 20A of this embodiment has a lens surface 20a (first surface), a bottom surface 20b (second surface), a first area 22, and second areas 23. The lens surface 20a and the bottom surface 20b are aligned in the direction intersecting with the substrate surface 7a (refer to FIG. 2) (for example, the direction of the normal line of the substrate surface 7a), and extend along the substrate surface 7a. The lens component 20A is made of, for example, resin.

The lens surface 20a is a surface facing the optical connector 30. The lens surface 20a has at least one lenses 21 optically coupled to each light reflection surface 17b on the CPU substrate 7. As an example, eight lenses 21 aligned in a line are illustrated in the figures. These lenses 21 are convex lenses. Each lens 21 is integrally formed with the lens component 20A by transferring a shape of a die having an inverted shape of the lens 21 at the time of molding of the lens component 20A, for example. Each lens 21 collimates the optical signal La reflected by the light reflection surface 17b to be emitted from the planar optical waveguide 13, and emits the optical signal La toward the optical connector 30. Additionally, each lens 21 condenses the optical signal La collimated by the optical connector 30 toward the light reflection surface 17b. Each lens surface 20a of this embodiment is composed of a bottom surface of a recess portion formed on an upper surface 20c of the lens component 20A. Consequently, it is possible to reduce dirt and dust adhered to the lens surface 20a, and to prevent contamination of the lens surface 20a. Additionally, it is possible to regulate an interval between the lenses 21 and the lens of the optical connector 30.

The bottom surface 20b is a surface located on a back side of the lens surface 20a, and facing the optical waveguide film 8A. The bottom surface 20b is formed flat, and receives the optical signal La reflected by the light reflection surface 17b to be emitted from the planar optical waveguide 13. Additionally, the bottom surface 20b emits the optical signal La going toward the light reflection surface 17b while being condensed by each lens 21. The bottom surface 20b is formed by transferring a flat surface of the die at the time of molding of the lens component 20A, for example.

The first area 22 is a block shaped area located between the lens surface 20a and the bottom surface 20b. The first area 22 transmits the optical signal La from the lens surface 20a to the bottom surface 20b, or from the bottom surface 20b to the lens surface 20a. In the lens component 20A, at least the first area 22 is made of a material transparent to the wave length of the optical signal La.

The second areas 23 are provided on at least both sides of the first area 22 in the direction along the substrate surface 7a. The second areas 23 each have a first end face 23a facing the substrate surface 7a, and a second end face 23b located on a back side of the first end face 23a and facing the optical connector 30. Both the first end face 23a and the second end face 23b are flat, and extend along the substrate surface 7a. A distance between the first end face 23a and the substrate surface 7a is shorter than a distance between the bottom surface 20b and the substrate surface 7a. In other words, the first end face 23a has a certain height h1 with respect to the bottom surface 20b. In an example, the height h1 is 45 μm to 55 μm. In this embodiment, the second end face 23b is in the same plane as the upper surface 20c, relative positional relation between the second end face 23b and the upper surface 20c in the direction intersecting with the substrate surface 7a is not limited to this.

The lens component 20A further has a guide hole 24 (first guide hole), and a guide hole 25 (second guide hole). The guide hole 24 is formed in the second area 23 located on one side of the first area 22 in the direction along the substrate surface 7a. The guide hole 25 is formed in the second area 23 located on the other side of the first area 22 in the direction along the substrate surface 7a. The guide holes 24, 25 extend in the direction intersecting with the first end faces 23a of the second areas 23, and are opened in the first end faces 23a and the second end faces 23b of the second areas 23. In other words, the guide holes 24, 25 penetrate between the first end faces 23a and the second end faces 23b along the optical axis direction of the optical signal La of the lens component 20A. In the guide holes 24, 25, guide pins for accurately positioning a relative position between the optical connector 30 and the lens component 20A are inserted from the sides of the second end faces 23b.

The guide hole 24 has a first hole part 24a, a second hole part 24b, and a third hole part 24c. The first hole part 24a extends from the first end face 23a toward an inner part of the second area 23, and has a uniform inner diameter over the extending direction. The second hole part 24b extends from the second end face 23b toward the inner part of the second area 23, and has a uniform inner diameter over the extending direction. However, the inner diameter of the first hole part 24a is smaller than the inner diameter of the second hole part 24b. The third hole part 24c is formed between the first hole part 24a and the second hole part 24b, and connects the first hole part 24a and the second hole part 24b. The inner diameter of one end on the first hole part 24a side of the third hole part 24c is equal to the inner diameter of the first hole part 24a, and the inner diameter of the other end on the second hole part 24b side of the third hole part 24c is equal to the inner diameter of the second hole part 24b. The inner diameter of the third hole part 24c gradually expands from the one end on the first hole part 24a side to the other end on the second hole part 24b side.

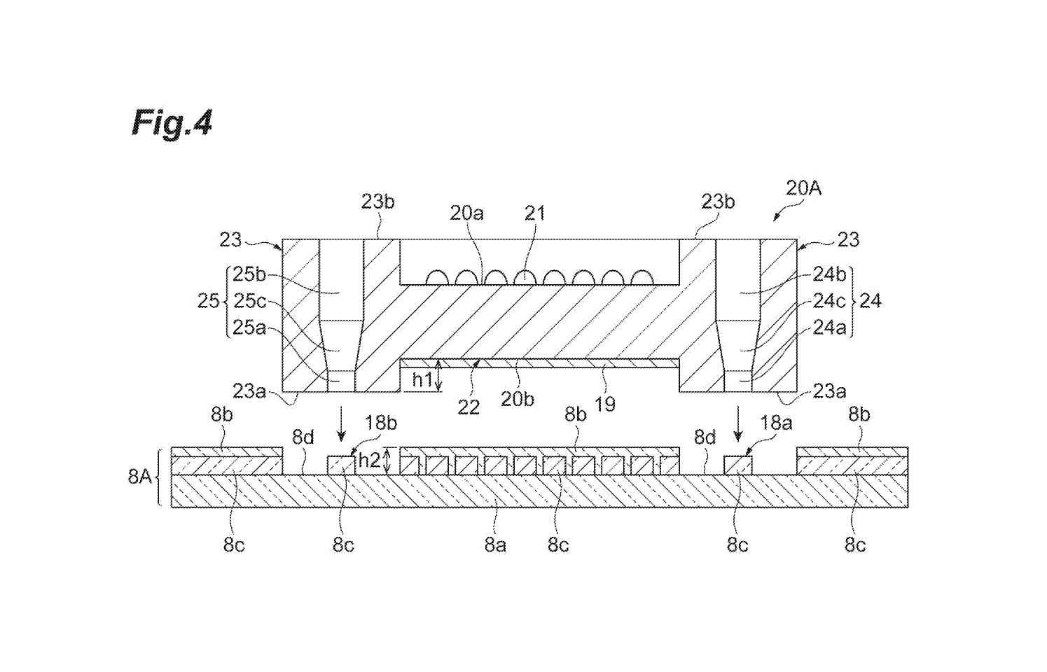

FIG. 4 is a sectional view illustrating a state in which the lens component 20A is mounted on the optical waveguide film 8A on the CPU substrate 7. As illustrated in FIG. 4, mounting surfaces 8d are formed on the optical waveguide film 8A. In the mounting surfaces 8d, the under-cladding layer 8a is exposed, and for example, the over-cladding layer 8b and the core layer 8c are removed, so that such mounting surfaces 8d are formed. Additionally, the mounting surfaces 8d are formed at such positions as to facing the first end faces 23a of the second areas 23. When the lens component 20A is mounted on the optical waveguide film 8A, the first end faces 23a and the mounting surfaces 8d come into contact with each other.

The optical waveguide film 8A has a projecting part 18a (first projecting part) and a projecting part 18b (second projecting part) in the respective mounting surfaces 8d. The projecting parts 18a, 18b are composed of at least the core layer 8c, and have columnar shapes. In this embodiment, the projecting parts 18a, 18b are composed of only the core layer 8c. When the lens component 20A is mounted on the optical waveguide film 8A, the projecting part 18a is fitted in the first hole part 24a of the guide hole 24, and the projecting part 18b is fitted in a first hole part 25a of the guide hole 25. Consequently, the lens component 20A and the optical waveguide film 8A are positioned to each other. Preferably, the diameters of the projecting parts 18a, 18b are substantially equal to the diameters of the guide holes 24, 25.

In an example, the inner diameter of the first hole part 24a is 0.1 mm to 0.5 mm, and the inner diameter of the second hole part 24b is 0.3 mm to 0.7 mm. The length of the first hole part 24a is larger than the heights of the projecting parts 18a, 18b (for example, thickness of the core layer 8c), and is, for example, 0.01 mm to 0.10 mm. The length of the second hole part 24b is, for example, 0.5 mm to 1.0 mm, and the length of the third hole part 24c is, for example, 0.5 mm to 1.0 mm.

The height h1 from the bottom surface 20b to each first end face 23a is larger than the height h2 from each mounting surface 8d to a surface of the optical waveguide film 8A. Accordingly, when the lens component 20A is mounted on the optical waveguide film 8A, a gap between the bottom surface 20b and the surface of the optical waveguide film 8A is generated in a state in which the first end face 23a is in contact with the mounting surface 8d. The optical connection structure 10 further comprises a refractive index matching agent 19 for filling this gap. The refractive index matching agent 19 is, for example, an adhesive transparent to the wavelength of the optical signal La.

Effects obtained by the thus described optical connection structure 10 of this embodiment will be described. In this optical connection structure 10, the respective second areas 23 have the guide holes 24, 25, the optical waveguide film 8A has the projecting part 18a fitted in the guide hole 24, and the projecting part 18b fitted in the guide hole 25. Therefore, the lens component 20A can be accurately positioned relative to the optical waveguide film 8A by this fitting. Additionally, since the core layer 8c is generally harder than the cladding layers 8a, 8b, the projecting parts 18a, 18b include at least the core layer 8c, so that it is possible to keep the strength of the projecting parts 18a, 18b. In addition, the heights h1 from the bottom surface 20b to the first end faces 23a are larger than the heights h2 from the mounting surfaces 8d to the surface of the optical waveguide film 8A, and therefore the first end faces 23a can reliably come into contact with the mounting surfaces 8d, and the guide holes 24, 25 can be reliably fitted to the projecting parts 18a, 18b, respectively.

Like this embodiment, the guide holes 24, 25 have openings in the second end faces 23b, so that the relative position between the optical connector 30 and the lens component 20A can be accurately positioned through the guide pins. The inner diameters of the first hole parts 24a, 25a are smaller than the inner diameters of the second hole parts 24b, 25b, the inner diameters of the third hole parts 24c, 25c gradually expand from the sides of the first hole parts 24a, 25a to the sides of the second hole parts 24b, 25b. Accordingly, when the guide holes 24, 25 are formed by rod-like dies, the rod-like dies are easily pulled out from the sides of the second hole parts 24b, 25b.

Like this embodiment, the refractive index matching agent 19 may be provided in the gap between the bottom surface 20b and the optical waveguide film 8A. Consequently, it is possible to suppress Fresnel reflection at the bottom surface 20b and the surface of the optical waveguide film 8A, and to reduce an optical loss. Furthermore, in this embodiment, the height h1 is larger than the height h2. Accordingly, even in a case where the refractive index matching agent 19 is provided, the first end faces 23a can be brought into contact with the mounting surfaces 8d, and it is possible to suppress axial deviation of each lens 21 to the optical signal La.

### Second Embodiment

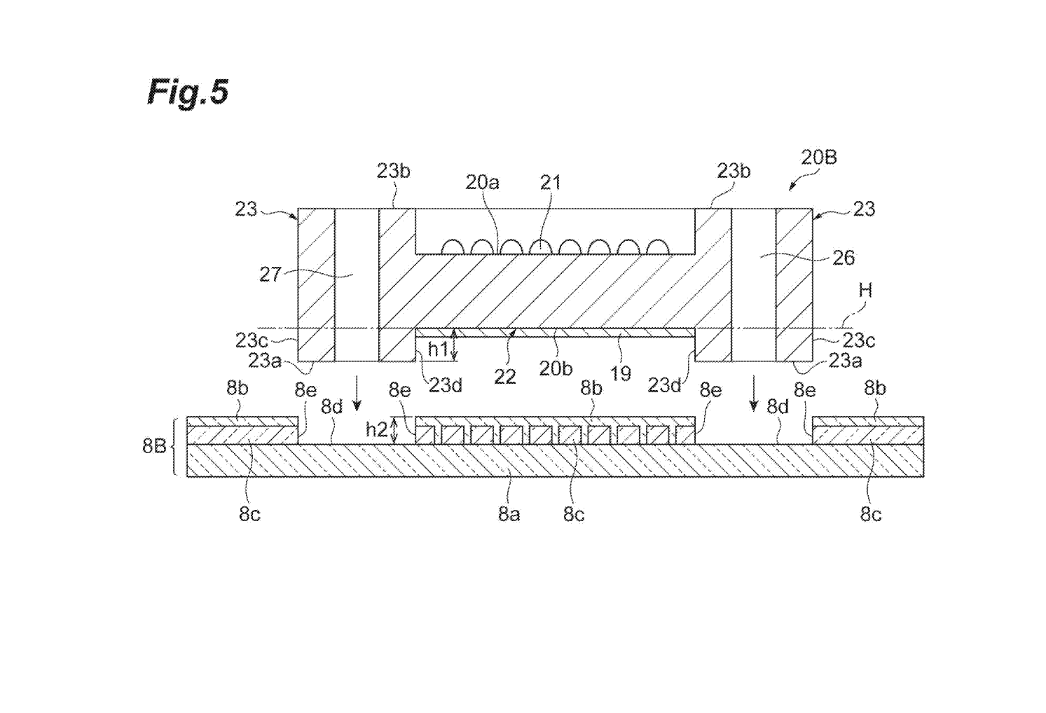

FIG. 5 is a sectional view partially enlarging and illustrating an optical coupling structure according to a second embodiment. This optical coupling structure comprises an optical waveguide film 8B and a lens component 20B in place of the optical waveguide film 8A and the lens component 20A of the first embodiment. The optical waveguide film 8B does not have the projecting parts 18a, 18b (refer to FIG. 4) unlike the optical waveguide film 8A of the first embodiment. Therefore, mounting surfaces 8d are flat over whole areas in contact with first end faces 23a.

The lens component 20B has a guide hole 26 (third guide hole) and a guide hole 27 (fourth guide hole) in place of the guide holes 24, 25. The guide hole 26 is formed in a second area 23 located on one side of a first area 22 in the direction along a substrate surface 7a. The guide hole 27 is formed in a second area 23 located on the other side of the first area 22 in the direction along the substrate surface 7a. The guide holes 26, 27 extend in the direction intersecting with the first end faces 23a of the second areas 23, and are opened in the first end faces 23a and second end faces 23b of the second areas 23. In other words, the guide holes 26, 27 penetrate between the first end faces 23a and the second end faces 23b along the optical axis direction of the optical signal La of the lens component 20B. In the guide holes 26, 27, guide pins for positioning a relative position between an optical connector 30 and the lens component 20B are inserted from the sides of the second end faces 23b. The guide holes 26, 27 of this embodiment each have a uniform inner diameter from one end on the first end face 23a side to the other end on the second end face 23b side, unlike the first embodiment.

Herein, a virtual plane H formed by extending a bottom surface 20b is defined. In this embodiment, when the lens component 20B is mounted on the optical waveguide film 8B, an outer surface 23c at a portion located on the substrate surface 7a side among two portions sectioned by the virtual plane H in each of the second areas 23 is in contact with a laminated end face 8e of the over-cladding layer 8b and the core layer 8c constituting a contour of the mounting surface 8d. Similarly, an inner surface 23d at the above portion of each of the second areas 23 is also in contact with a laminated end face 8e of the over-cladding layer 8b and the core layer 8c constituting a contour of the mounting surface 8d. Consequently, the lens component 20B can be accurately positioned relative to the optical waveguide film 8B. In this embodiment, the outer surfaces of the second areas 23 extend straight from the second end faces 23b to the first end faces 23a, the outer surfaces 23c are each equivalent to a part of such an outer surface. Therefore, in a plan view of the lens component 20B as viewed from the direction of a normal line of the substrate surface 7a, the outer surfaces 23c constitute a contour line of the lens component 20B.

Similarly to the first embodiment, the heights h1 from the bottom surface 20b to the first end faces 23a are larger than the heights h2 from the mounting surface 8d to the surface of the optical waveguide film 8A. Consequently, the first end faces 23a can be reliably brought into contact with the mounting surfaces 8d, and the outer surfaces 23c and the inner surfaces 23d can be reliably brought into contact with the laminated end faces 8e. Like this embodiment, the guide holes 26, 27 have openings in the second end faces 23b, so that a relative position between the optical connector 30 and the lens component 20B can be accurately positioned through guide pins.

The optical connection structure according to the present invention is not limited to the above embodiments, and other various modifications can be performed. For example, the above respective embodiments may be combined in accordance with necessary purpose and effect. In the above embodiments, the present invention is applied to the substrate apparatus in the server system, but is not limited to this. The present invention can be applied to various substrate apparatuses having a planar optical waveguide.

### REFERENCE SIGNS LIST

1A substrate apparatus
3 backplane
5 base
6 CPU
7 CPU substrate
7a substrate surface
8A, 8B optical waveguide film
8a under-cladding layer
8b over-cladding layer
8c core layer
8d mounting surface
8e laminated end face
9 memory substrate
10 optical connection structure
11 light receiving/emitting element
11a VCSEL
11b photodiode
13 planar optical waveguide
15 input/output port
17a, 17b light reflection surface
18a, 18b projecting part
19 refractive index matching agent
20A, 20B lens component
20a lens surface
20b bottom surface
20c upper surface
21 lens
22 first area
23 second area
23a first end face
23b second end face
23c outer surface
23d inner surface
24, 25 guide hole
24a, 25a first hole part
24b, 25b second hole part
24c, 25c third hole part
26, 27 guide hole
30 optical connector
31 inter-substrate optical waveguide
32 optical waveguide
33 optical fiber
H virtual plane
La optical signal

1. An optical connection structure comprising:
an optical waveguide film including a planar optical waveguide formed on a substrate surface, and a light reflection surface inclined to both a normal line of the substrate surface and an optical axis of the planar optical waveguide; and
a lens component provided on the optical waveguide film, and having a lens optically coupled to the light reflection surface, wherein
the optical waveguide film has an under-cladding layer, an over-cladding layer provided over the under-cladding layer, and a core layer provided between the under-cladding layer and the over-cladding layer,
the lens component has a first surface having the lens, a second surface located on a back side of the first surface, and facing the optical waveguide film, a first area located between the first surface and the second surface, and transmitting light, and second areas provided on at least both sides of the first area in a direction along the substrate surface,
the optical waveguide film has mounting surfaces to which the under-cladding layer is exposed, the mounting surfaces facing the second areas,
the respective second areas have a first guide hole formed on one side of the first area, and a second guide hole formed on another side of the first area, the first guide hole and the second guide hole being opened in respective first end faces facing the mounting surfaces, and
the optical waveguide film has a first projecting part composed of at least the core layer, and fitted in the first guide hole, and a second projecting part composed of at least the core layer, and fitted in the second guide hole, in the respective mounting surfaces, and
a height from the second surface to each of the first end faces is larger than a height from each of the mounting surfaces to a surface of the optical waveguide film.

2. The optical connection structure according to claim 1, wherein
the first guide hole and the second guide hole penetrate as far as second end faces located on the back side of the first end face, and each have a first hole part extending from the first end face, a second hole part extending from the second end face, and a third hole part connecting the first hole part and the second hole part,
an inner diameter of each of the first hole parts is smaller than an inner diameter of each of the second hole parts, and
an inner diameter of each of the third hole parts gradually expands from one end on a side of the first hole part to another end on a side of the second hole part.

3. An optical connection structure comprising:
an optical waveguide film including a planar optical waveguide formed on a substrate surface, and a light reflection surface inclined to both a normal line of the substrate surface and an optical axis of the planar optical waveguide; and
a lens component provided on the optical waveguide film, and having a lens optically coupled to the light reflection surface, wherein
the optical waveguide film has an under-cladding layer, an over-cladding layer provided over the under-cladding layer, and a core layer provided between the under-cladding layer and the over-cladding layer,
the lens component has a first surface having the lens, a second surface located on a back side of the first surface, and facing the optical waveguide film, a first area located between the first surface and the second surface, and transmitting light, and second areas provided on at least both sides of the first area in a direction along the substrate surface,
the optical waveguide film has mounting surfaces to which the under-cladding layer is exposed, the mounting surfaces facing the second areas,
an outer surface at a portion located on a side of the substrate surface among two portions sectioned by a plane obtained by extending the second surface in each of the second areas is in contact with a laminated end face of the core layer and the over-cladding layer constituting a contour of the mounting surface, and
a height from the second surface to a first end face of each of the second areas facing the mounting surface is larger than a height from each of the mounting surfaces to a surface of the optical waveguide film.

4. The optical connection structure according to claim 3, wherein
the respective second areas have a third guide hole formed on one side of the first area, and a fourth guide hole formed on another side of the first area, the third guide hole and the fourth guide hole being opened in respective second end faces located on back sides of the first end faces.

5. The optical connection structure according to claim 1, further comprising a refractive index matching agent filling a gap between the second surface and the optical waveguide film.
